(19) United States
(12) Patent Application Publication
(10) Pub. No.: US 2008/0248610 A1
(43) Pub. Date: Oct. 9, 2008

(54) THERMAL BONDING PROCESS FOR CHIP PACKAGING

(75) Inventors: Hwee Seng Chew, Singapore (SG); Chee Kian Ong, Singapore (SG); Balasubramanian Sivagnanam, Singapore (SG)

Correspondence Address: LAWRENCE Y.D. HO & ASSOCIATES PTE LTD, 30 BIDEFORD ROAD, #02-02, THONGSIA BUILDING, SINGAPORE, 229922, SG

(73) Assignee: Advanpack Solutions Pte Ltd, Singapore (SG)

(21) Appl. No.: 11/695,618

(22) Filed: Apr. 3, 2007

(51) Int. Cl. H01L 21/00

(52) U.S. Cl. 438/108

(57) ABSTRACT

The present invention provides a thermal bonding process for chip packaging. In accordance with an aspect of the invention, there is provided an approach to solve the problems caused by the different CTEs between the die and the substrate. It discloses an improved thermal bonding process for forming pillar-shaped interconnection, which controls the thermal expansion of the semiconductor die and the substrate by applying differential heating temperature to the two, thereby minimizing the misalignment between the die and the substrate, overcoming the stresses imposed on the interconnection and allowing more reliable and accurate packaging.

### FIELD OF THE INVENTION

The present invention relates generally to semiconductor chip packaging and, in particular to forming more precise and reliable interconnection between a semiconductor die and a substrate by applying differential heating temperatures to the die and the substrate.

### BACKGROUND

A semiconductor chip package usually comprises a semiconductor die mounted onto a substrate by a plurality of solder bump interconnection. The conventional method for forming a solder bump interconnection utilizes a microball composed of tin-lead solder alloy. The microball is deposited onto a planar interface of the semiconductor die. The die is then assembled with the substrate wherein the bump of the microball rests upon the receiving conductive portion of the substrate. The assembly is heated and cooled to form a solder joint, thereby bonding the die to the substrate. A method for forming a pillar-shaped interconnection is disclosed in the U.S. Pat. No. 6,592,019. The interconnection system comprises an elongated pillar made of copper, gold or other materials with high reflow temperature, and a solder tip on one end of the pillar. It has been proposed to achieve finer pitches between adjacent interconnects with minimum probability of bump bridging.

The semiconductor die and the substrate are generally made of different materials. The different materials may have significantly different coefficients of thermal expansion (CTE). With respect to FIG. 1, in accordance with the prior art, there is provided a cross-sectional view of a semiconductor die and a substrate after the heating step of the conventional thermal compression bonding process. The semiconductor die 11′ has a plurality of pillars 12′ on the planar surface facing the substrate 15′. The substrate 15′ has a plurality of receiving conductive portions 14′ on the planer surface facing the die 11′. Generally, the CTE of the die 11′ is less than the CTE of the substrate 15′. As a result, when the die 11′ and the substrate 15′ undergo the heating step of the conventional thermal bonding process, the distance D1′ between the neighboring pillars 12′ becomes smaller than the distance D2′ between the neighboring receiving conductive portions 14′. The subsequent bonding will, therefore, be misaligned and cause crack of the pillars in the subsequent cooling down process. In other words, during thermal cycling such as typically experienced by the semiconductor package during operation, the die and the substrate tend to expand and contract at different rates. This creates stresses that produce fatigue within the solder bonds and may result in catastrophic failure of the interconnection. Especially, when the pillar-shaped interconnection system is adopted, misalignment between the pillars of the die and the receiving conductive portions of the substrate will be observed after the thermal bonding process. Even worse, the pillars tend to bend and crack under the stresses.

### SUMMARY

In accordance with an aspect of the invention, there is provided an approach to solve the problems caused by the different CTEs between the die and the substrate from a different angle. It discloses an improved thermal bonding process for forming pillar-shaped interconnection, which controls the thermal expansion of the semiconductor die and the substrate by applying differential heating temperature to the two, thereby minimizing the misalignment between the die and the substrate, overcoming the stresses imposed on the interconnection and allowing more reliable and accurate packaging.

In accordance with an aspect of the present invention, the improved thermal bonding process comprises the following steps. Provide a substrate having a plurality of receiving conductive portions on an upper planar surface and a semiconductor die having a plurality of pillars on a surface facing the upper surface of the substrate. Then control the semiconductor die at a first temperature and control the substrate at a second temperature. The first temperature is higher than the second temperature. Melt solder portions between the plurality of pillars and the plurality of receiving conductive portions and bond the plurality of pillars and the plurality of receiving conductive portions with the solder portions.

### BRIEF DESCRIPTION OF THE DRAWINGS

Preferred embodiments according to the present invention will now be described with reference to the Figures, in which like reference numerals denote like elements.

FIG. 1 shows a cross-sectional view of a semiconductor die and a substrate after the heating step of the thermal compression bonding process in accordance with the prior art.

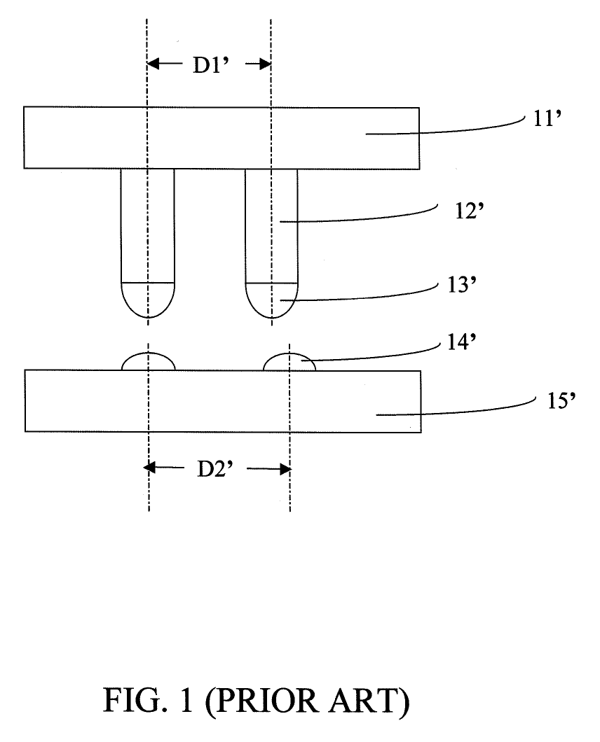

FIG. 2 shows a flowchart of the thermal bonding process in accordance with a preferred embodiment of the present invention.

FIG. 3 shows a cross-sectional view of a semiconductor die and a substrate after the heating step of the thermal bonding process in accordance with a preferred embodiment of the present invention.

FIG. 4 shows a cross-sectional view of a semiconductor die and a substrate after the bonding step of thermal boding process in accordance with a preferred embodiment of the present invention.

### DETAILED DESCRIPTION

The present invention may be understood more readily by reference to the following detailed description of certain embodiments of the invention. However, it will be understood by those skilled in the relevant art that the present invention may be practiced without these specific details. In other instances, well-known methods, procedures, and components have not been described in detail so as not to obscure the present invention.

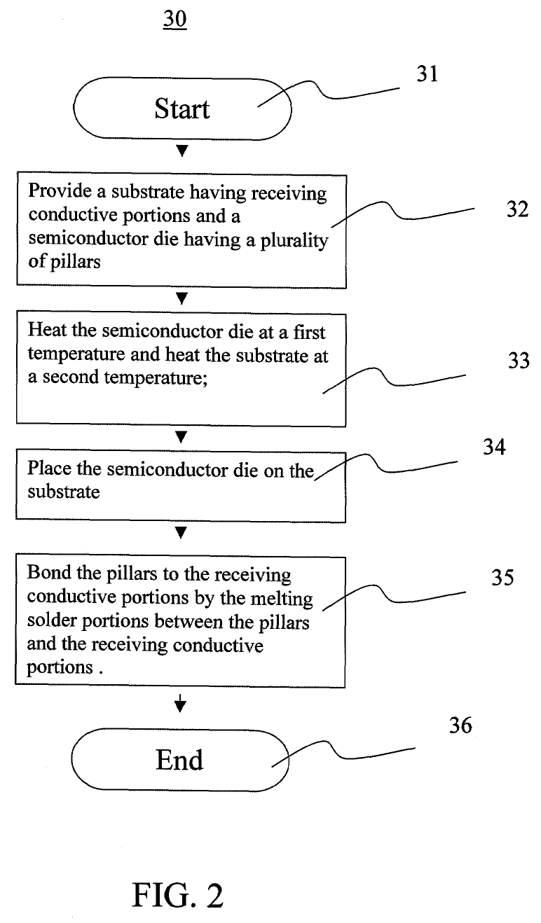

Please referring to FIG. 2, there is provided a flowchart of a thermal compression bonding process for chip packaging in accordance with an embodiment of the present invention. The flowchart will be described briefly herein while detail will be discussed later. In step 32, a substrate having a plurality of receiving conductive portions and a semiconductor die having a plurality of pillars are provided for processing. The die is heated at a first temperature while the substrate is heated at a second temperature in step 33. The heated die will then be aligned with and placed on to the heated substrate in step 34. By the melting solder portions between the pillars of the die and the receiving conductive portions of the substrate, the die will be mounted onto the substrate via the solder bond joints in step 35.

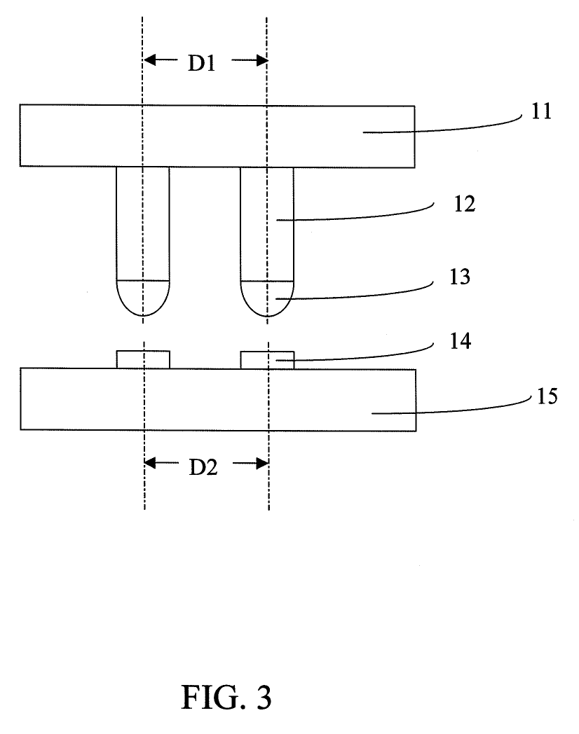

Now referring to FIG. 3, there is provided a cross-sectional view of a semiconductor die and a substrate after the heating step of the thermal compression bonding process in accordance with an embodiment of the present invention. The semiconductor die 11 comprises a plurality of pillars 12, the limitation of pitch and spacing restricted by bumping process. The pitch means the distance between two central points of the adjacent pillars. Typically a pitch of 80 to 150 microns corresponding to a spacing of 33 micron to 60 micron on the planar surface facing the substrate 15, each pillar having a solder tip 13 at the end close to the substrate 15. The substrate 15 comprises a pattern layer of receiving conductive portions 14, the limitation of pitch and spacing restricted by the process of establishing conductive portion. The distribution pattern of the receiving conductive portions 14 on the substrate 15 matches the pattern of the pillars 12 on the semiconductor die 11. Typically the spacing of the receiving conductive portions 14 can go even to 30 μm which are receiving traces for receiving electronic signal from the die via the corresponding pillars 12 and solder tips 13 after the pillar-shaped interconnection is formed by the thermal compression bonding process. The die 11 is generally made of the material selected from the group of semiconductors, Silicon, Gallium compounds or Indium compounds. As a result, the CTE of the substrate is normally between 2˜10 ppm/° C., preferably, is between 2˜6 ppm/° C. In this embodiment, silicon is used and the corresponding CTE of the die is about 2.3 ppm/° C. The pillars 12 are typically copper pillars. However, it would be obvious for those skilled in the art to make pillars of any other conductor that has higher melting point than the solder. While in this embodiment the solder tips 13 are set up on the tips of the pillars 12 only, they could also be set up on the receiving conductive portions 14 only or on both of the pillars 12 and receiving conductive portions 14. The substrate 15 is generally selected from organic substrates such as FR4 and BT resin, or from Ceramic substrates like alumina, aluminum nitride and zirconia. The CTE of the substrate 15 is generally between 5˜60 ppm/° C., preferably, is between 5˜25 ppm/° C. In this embodiment, BT Resin is used and the corresponding CTE of the substrate 15 is about 8˜20 ppm/° C.

Still referring to FIG. 3, in accordance with the above embodiment, the heating step of the thermal compression bonding process is applied to the die 11 and the substrate 15. The die 11 is heated to the first temperature T1 within the workable rage from 170 to 350° C., preferably between 200 to 250° C. The substrate 15 is heated to the second temperature T2 within the workable range from 50 to 200° C., preferably between 75 and 125° C. Due to the differential heating temperatures applied, the thermal expansion of the die 11 and the substrate 15 is controlled so that in the bonding step the distance D1 between the neighboring pillars 12 remains approximately the same as the distance D2 between the neighboring receiving conductive portions 14. The pillars 12 are still aligned with the conductive receiving portions 14.

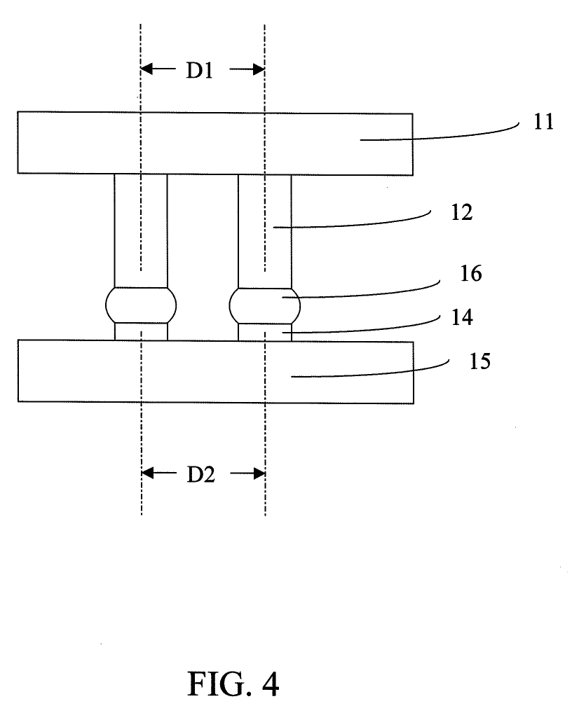

Now referring to FIG. 4, there is provided a cross-sectional view of a semiconductor die and a substrate after the bonding step of the thermal compression boding process in accordance with an embodiment of the present invention. A force within the workable range from 5 to 100 Newton (N), preferably between 5 and 30 Newton (N), is applied on the die 11, whose typical size ranges from 10×10 mm² to 30×30 mm², for a period of 2 to 40 seconds so that the solder tips 13 melt and form the solidified joints 16 between the aligned pillars 12 and receiving conductive portions 14. The solder height could be in the range of 50 to 100 micron. After the bonding step, cool the die 11 and the substrate 15 in different temperature to ensure that the distance D1 between the neighboring pillars 12 remains approximately the same as the distance D2 between the neighboring receiving conductive portions 14. Therefore, the pillars 12 won't bend or crack under the stresses in the cooling process and finally remain well aligned in room temperature.

While the present invention has been described with reference to a particular embodiment, it will be understood that the embodiments are illustrative and that the invention scope is not so limited. Alternative embodiments of the present invention will become apparent to those having ordinary sill in the art to which the present invention pertains. Such alternate embodiments are considered to be encompassed within the spirit and scope of the present invention. Accordingly, the scope of the present invention is described by the appended claims and is sported by the foregoing description.

What is claimed is:

1. A process for chip packaging comprising the steps of:
providing a substrate having a plurality of receiving conductive portions on an upper surface;
providing a semiconductor die having a plurality of pillars on a surface facing the upper surface of the substrate;
controlling the semiconductor die at a first temperature;
controlling the substrate at a second temperature;
melting solder portions between the plurality of pillars and the plurality of receiving conductive portions; and
bonding the plurality of pillars and the plurality of receiving conductive portions with the solder portions;
wherein the first temperature is higher than the second temperature.

2. The process of claim 1, wherein the first temperature is between 170˜350° C., and the second temperature is between 50˜200° C.

3. The process of claim 2, wherein the first temperature is between 200˜250° C., and the second temperature is between 75˜125° C.

4. The process of claim 1, wherein the CTE of the substrate is between 5˜60 ppm/° C., and the CTE of the semiconductor die is between 2˜10 ppm/° C.

5. The process of claim 4, wherein the CTE of the substrate is between 5˜25 ppm/° C., and the CTE of the semiconductor die is between 2˜5 ppm/° C.

6. The process of claim 5, wherein the substrate is selected from the group of organic substrates and Ceramic substrates.

7. The process of claim 6, wherein the organic substrate is selected from the group of FR4 and BT resin.

8. The process of claim 1, wherein the die is selected from the group of semiconductors, Silicon, Gallium compounds and Indium compounds.

9. A process for chip packaging comprising the steps of:
providing a substrate having a plurality of receiving conductive portions on an upper surface wherein two of the adjacent receiving conductive portions having a first distance;
providing a semiconductor die having a plurality of pillars on a surface facing the upper surface of the substrate wherein two of the adjacent pillars having a second distance;
adjusting the first distance and the second distance by different thermal steps; and
bonding the plurality of pillars to the plurality of receiving conductive portions;
wherein the first distance is substantially the same as the second distance in the bonding step.

10. The process of claim 9, wherein adjusting the first distance is by heating the substrate at a first temperature between 200˜250° C.

11. The process of claim 9, wherein adjusting the first distance is by heating the semiconductor die at a second temperature 75˜125° C.

12. The process of claim 9, wherein the CTE of the substrate is between 5˜60 ppm/° C., and the CTE of the semiconductor die is between 2˜10 ppm/° C.

13. The process of claim 12, wherein the CTE of the substrate is between 5˜25 ppm/° C., and the CTE of the semiconductor die is between 2˜5 ppm/° C.

14. The process of claim 13, wherein the substrate is selected from the group of organic substrates and Ceramic substrates.

15. The process of claim 14, wherein the organic substrate is selected from the group of FR4 and BT resin.

16. The process of claim 9, wherein the die is selected from the group of semiconductors, Silicon, Gallium compounds and Indium compounds.

17. A process for chip packaging comprising the steps of:
providing a substrate having a plurality of receiving conductive portions and said substrate having a first CTE value;
providing a semiconductor die having a plurality of pillars and having a second CTE value;
adjusting the first distance by heating the substrate at a first temperature;
adjusting the second distance by heating the semiconductor die at a second temperature;
bonding the plurality of pillars to the plurality receiving conductive portions with solders; and
wherein the plurality of pillars are substantially aligned with the plurality of receiving conductive portions in the bonding step.

18. The process of claim 9, wherein the first CTE is about 5˜60 ppm/° C., and the second CTE is about 2˜10 ppm/° C.

19. The process of claim 18, wherein the first CTE value is 5˜25 ppm/° C., and the second CTE value is 2˜5 ppm/° C.

20. The process of claim 17, further comprising of the steps of;
cooling the substrate at a third temperature after the bonding step; and
cooling the semiconductor die at a fourth temperature;
wherein the third temperature and the fourth temperature are different to ensure the plurality of pillars and the plurality of receiving conductive portions being aligned.
